(19) United States
(12) Patent Application Publication
(10) Pub. No.: US 2012/0126233 A1
(43) Pub. Date: May 24, 2012

(54) THIN FILM TRANSISTOR ARRAY PANEL AND METHOD FOR MANUFACTURING THE SAME

(76) Inventors: Chong Sup CHANG, Hwaseong-si (KR); Yoon Ho KHANG, Yongin-si (KR); Hyung Jun KIM, Yongin-si (KR); Se Hwan YU, Seoul (KR); Sang Ho PARK, Suwon-si (KR); Su-Hyoung KANG, Bucheon-si (KR); Myoung Geun CHA, Seoul (KR); Young Ki SHIN, Seoul (KR); Ji Seon LEE, Yongin-si (KR)

(21) Appl. No.: 13/078,790

(22) Filed: Apr. 1, 2011

(30) Foreign Application Priority Data
Nov. 23, 2010 (KR) 10-2010-0116896

(51) Int. Cl. H01L 29/786; H01L 21/336

(52) U.S. Cl. 257/59; 438/158; 257/E29.273; 257/E21.409

(57) ABSTRACT

Provided is a thin film transistor array panel. A thin film transistor array panel according to an exemplary embodiment includes a gate wire having a first region where the gate line is disposed, and a second region where the gate electrode is disposed, and a thickness of the gate wire formed in the first region is greater than the thickness of the gate wire that is formed in the second region.

### CROSS-REFERENCE TO RELATED APPLICATION

This application claims priority to and the benefit of Korean Patent Application No. 10-2010-0116896 filed in the Korean Intellectual Property Office on Nov. 23, 2010, the entire contents of which are incorporated herein by reference.

### BACKGROUND

(a) Field of the Invention

The subject matter disclosed herein relates to a thin film transistor array panel and a manufacturing method thereof.

(b) Description of the Related Art

In general, a flat panel display such as a liquid crystal display or an organic light emitting diode display includes a pair of field generating electrodes and an electro-optical active layer that is disposed therebetween. In the case of the liquid crystal display, a liquid crystal layer is included as the electro-optical active layer, and in the case of the organic light emitting diode display, an organic emission layer is included as the electro-optical active layer.

In an organic light emitting diode display, one of the field generating electrodes in the pair is generally connected to a switching element and supplied with an electric signal. The electro-optical active layer displays an image by converting the electric signal to an optical signal.

In the flat panel display, a thin film transistor (TFT) that is a three terminal element is used as a switching element. Signal lines such as a gate line that transmits a scanning signal to control the thin film transistor, and a data line that transmits a signal to be applied to the pixel electrode are provided.

Meanwhile, as the area of the display device is increased, the signal line is increased, such that resistance is increased. If the resistance is increased as described above, problems such as signal delay or voltage drop may occur, and it is necessary to form the signal line using a material having a low specific resistance in order to solve the problems. A representative material among materials having low specific resistance is copper (Cu).

The above information disclosed in this Background section is only for enhancement of understanding of the background of the invention and therefore it may contain information that does not form the prior art that is already known to a person of ordinary skill in the art.

### SUMMARY

Although a signal line may be formed of a material having low specific resistance, it is difficult to obtain sufficiently low resistance.

The claimed subject matter has been made in an effort to provide a thin film transistor array panel that reduces resistance by selectively forming a thick signal line, and a method for manufacturing the same.

An exemplary embodiment of the claimed subject matter provides a thin film transistor array panel including a gate wire having a first region where the gate line is disposed and a second region where the gate electrode is disposed, wherein the thickness of the gate wire formed in the first region is greater than the thickness of the gate wire that is formed in the second region.

The thin film transistor array panel may further include an interlayer insulating layer disposed on the gate line and a blocking layer disposed between the gate electrode and the interlayer insulating layer.

The blocking layer may be formed of an organic layer or an inorganic layer.

The inorganic layer may include silicon nitride (SiNx).

The gate line may include a lower gate line disposed at a same layer as the gate electrode and an upper gate line disposed on the lower gate line.

The thin film transistor array panel may further include a data line intersecting the gate line, wherein a lower data line disposed at a same layer as the gate electrode and an upper data line disposed on the lower data line.

The data line may be connected by a first bridge at an intersection part of the gate line and the data line.

The thin film transistor array panel may further include a source electrode disposed on a semiconductor layer and a drain electrode disposed at an opposite side of the source electrode with respect to the gate electrode, wherein the source electrode and the data line may be connected by a second bridge.

The thin film transistor array panel may further include a passivation layer disposed on the source electrode and the drain electrode, wherein a first seed layer may be disposed between the passivation layer and the first bridge.

A second seed layer may be disposed between the passivation layer and the second bridge.

The thin film transistor array panel may further include a pixel electrode disposed on the passivation layer and an organic layer disposed between the passivation layer and the pixel electrode.

The organic layer may be a color filter.

Another exemplary embodiment of the present invention provides a method for manufacturing a thin film transistor array panel, including: forming a gate wire including a lower gate line extending in a fitst direction on a substrate and a gate electrode protruding from the lower gate line, and a lower data line extending in a second direction intersecting the first direction; forming a blocking layer on the gate electrode; forming an upper gate line and an upper data line on the lower gate line and the lower data line; forming an interlayer insulating layer covering the gate wire and upper data line; forming a semiconductor layer on the interlayer insulating layer; forming a source electrode disposed on the semiconductor layer and a drain electrode disposed at an opposite side of the source electrode with respect to the gate electrode; forming a passivation layer disposed on the source electrode and drain electrode; and forming a pixel electrode disposed on the passivation layer.

The lower gate line, the gate electrode and the lower data line may be formed by using a sputtering method.

The forming of the upper gate line and the upper data line may use the lower gate line and the lower data line as a seed layer according to an electroless plating method or an electroplating method.

The first blocking layer may be formed of an organic layer or an inorganic layer.

The inorganic layer may include silicon nitride (SiNx).

The thin film transistor array panel may further include forming a first bridge that connects the upper data line at an intersection part of the upper gate line and the upper data line.

The forming of the first bridge may include forming a first seed layer on the passivation layer after the forming of the passivation layer, forming a first photosensitive film and a second photosensitive film having different thicknesses on the first seed layer, exposing a portion of the upper data line by etching the first seed layer, the passivation layer, and the interlayer insulating layer by using the first photosensitive film and the second photosensitive film as a mask, etchbacking the first photosensitive film in order to remove the first photosensitive film, etching the first seed layer not covered by the second photosensitive film, exposing the first seed layer by removing the second photosensitive film, and forming the first bridge by using the exposed first seed layer and exposed upper data line as the seed layer using an electroless plating method or an electroplating method, wherein the first photosensitive film has a smaller thickness than the second photosensitive film.

The first photosensitive film may overlap the upper data line, and the second photosensitive film may be disposed at an intersection part of the upper gate line and the upper data line.

The thin film transistor array panel may further include forming a second bridge that connects the source electrode and the upper data line.

The forming of the second bridge may include forming a second seed layer on the passivation layer after the forming of the passivation layer, forming a third photosensitive film and a fourth photosensitive film having different thicknesses on the second seed layer, exposing a portion of the upper data line by etching the second seed layer, the passivation layer, and the interlayer insulating layer by using the third photosensitive film and the fourth photosensitive film as a mask, etchbacking the third photosensitive film in order to remove the third photosensitive film, etching the second seed layer not covered by the fourth photosensitive film, exposing the second seed layer by removing the fourth photosensitive film, and forming the second bridge by using the exposed second seed layer and exposed upper data line as the seed layer using an electroless plating method or an electroplating method, wherein the third photosensitive film may have a smaller thickness than the fourth photosensitive film.

The forming of the lower gate line, the lower data line and the blocking layer may include forming a wiring layer and a blocking material layer on the substrate, forming photosensitive film patterns having different thicknesses on the wiring layer and the blocking material layer, sequentially etching the blocking material layer and the wiring layer by using the photosensitive film pattern as a mask, exposing a portion of an upper side of the blocking material layer by etchbacking the photosensitive film pattern, etching an exposed portion of the blocking material layer by using the photosensitive film pattern as the mask, and removing the photosensitive film pattern.

According to one exemplary embodiment, resistance can be reduced by covering a thin film transistor region in which a channel region is formed with a blocking layer so that only a thickness of a longitudinally extending wiring part is increased.

### BRIEF DESCRIPTION OF THE DRAWINGS

FIG. 1 is a layout view of a thin film transistor array panel according to an exemplary embodiment.

FIG. 2 is a cross-sectional view that is taken along the line II-II′ of FIG. 1.

FIG. 3 is a cross-sectional view that is taken along the line III-III′ of FIG. 1.

FIGS. 4 to 26 are layout views and cross-sectional views that illustrate a manufacturing method of a thin film transistor array panel according to another exemplary embodiment.

### DETAILED DESCRIPTION

The claimed subject matter will be described more fully hereinafter with reference to the accompanying drawings, in which exemplary embodiments are shown. As those skilled in the art would realize, the described embodiments may be modified in various ways, all without departing from the spirit or scope of the claimed subject matter. The exemplary embodiments proposed herein are provided to make the description clearly and fully understood, and to sufficiently provide the scope of the claimed subject matter to a person of an ordinary skill in the art.

In the drawings, the size and the thickness of the device may be exaggerated for the clearness. It will be understood that when an element such as a layer, film, region, or substrate is referred to as being “on” another element, it can be directly on the other element or intervening elements may also be present. Like reference numerals designate like components throughout the specification.

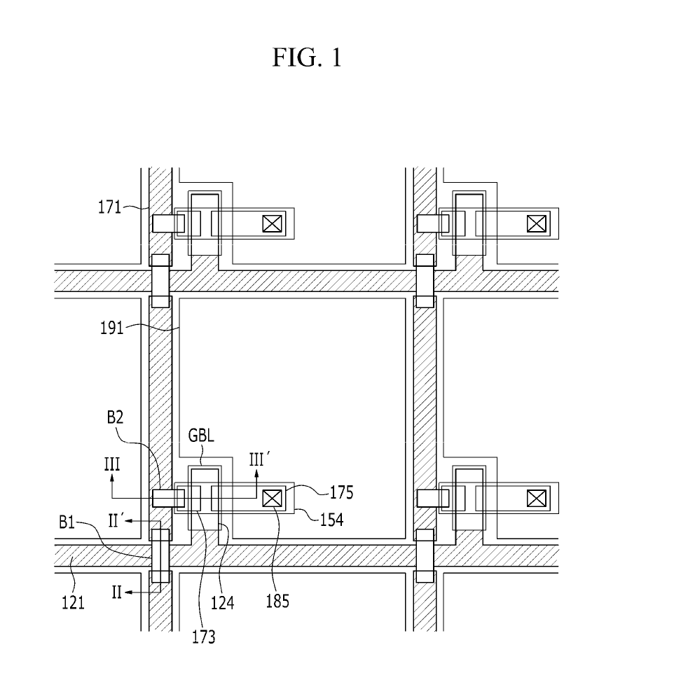

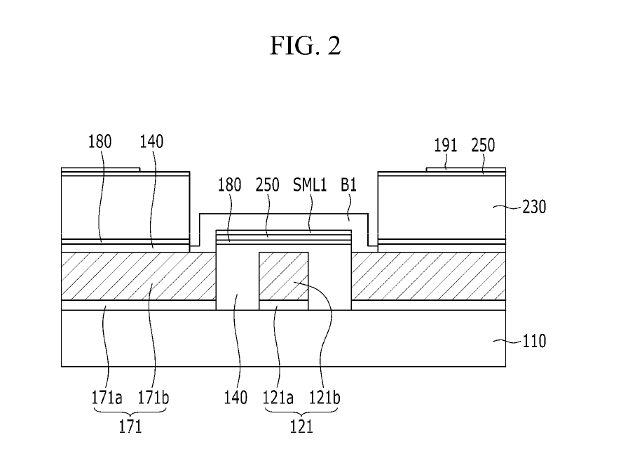

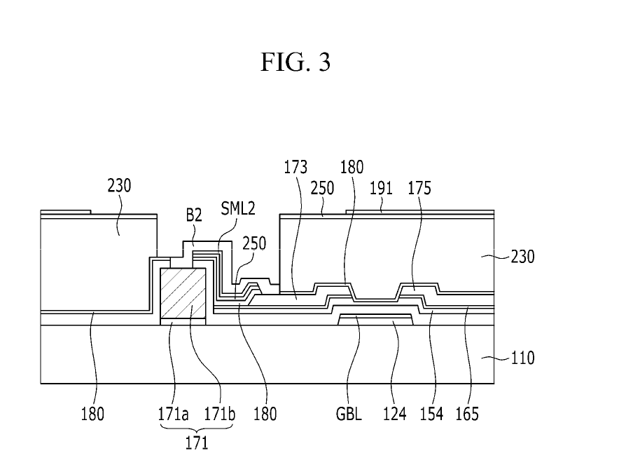

FIG. 1 is a layout view of a thin film transistor array panel according to an exemplary embodiment. FIG. 2 is a cross-sectional view that is taken along the line II-II′ of FIG. 1. FIG. 3 is a cross-sectional view that is taken along the line III-III′ of FIG. 1.

With reference to FIGS. 1 to 3, a gate line 121 and a data line 171 are disposed on a substrate 110 that is made of transparent glass or plastic.

The gate line 121 transfers a gate signal and mainly extends in a horizontal direction. The gate line 121 according to an exemplary embodiment includes a lower gate line 121a that longitudinally extends in a horizontal direction, an upper gate line 121b that is disposed on the lower gate line 121a, a gate electrode 124 that protrudes from the lower gate line 121a, and a wide gate pad (not shown) for connection with another layer or external driving circuit.

A blocking layer GBL is disposed on the gate electrode 124. The upper gate line 121b may be disposed on the entire upper surface of the lower gate line 121a that is not covered by the blocking layer GBL. That is, the upper gate line 121b is not disposed on the gate electrode 124. The upper gate line 121b may have the same shape in a top view as the lower gate line 121a with the exception of the part corresponding to the gate electrode 124.

The blocking layer GBL may be formed of an organic layer or a silicon nitride (SiNx). The lower gate line 121a and gate electrode 124 may be formed by using a sputtering method, and the upper gate line 121b may be formed by using the lower gate line 121a as a seed layer according to an electroless plating method or an electroplating method.

The gate line 121 may be made of an aluminum-based metal such as aluminum or an aluminum alloy having a low specific resistance. However, the gate line 121 may be made of silver-based metal such as silver or a silver alloyDeletedTextscopper-based metal such as copper or a copper alloy, molybdenum-based metal such as molybdenum or a molybdenum alloy, chromium, tantalum and titanium, and may have a multilayer structure that includes two conductive layers (not shown) having different physical properties.

In detail, the upper gate line 121b and lower gate line 121a may be formed of the same material, or not be formed of the same material.

The data line 171 transmits a data signal and mainly extends in a vertical direction and crosses the gate line 121. The data line 171 according to the exemplary embodiment includes a lower data line 171a that longitudinally extends in a horizontal direction, an upper data line 171b that is disposed on the lower data line 171a, and a data pad (not shown) for connection to the other layer or external driving circuit, which is an end portion having a wide area.

Herein, the data line 171 is separated from the gate line 121 at an intersection thereof. The gate line 121 passes through at the portion in which the data line 171 is separated, the data line 171 and gate line 121 are separated from each other, and the separated portion may be filled by an interlayer insulating layer 140 as described below.

An interlayer insulating layer 140 that is made of silicon nitride (SiNx) or silicon oxide (SiO₂) is disposed on the gate line 121, blocking layer GBL, and data line 171.

The semiconductor layer 154 that is formed of hydrogenated amorphous silicon or polysilicon is disposed on the interlayer insulating layer 140. Ohmic contact layers 163 and 165 are disposed on the semiconductor layer 154. The ohmic contact layers 163 and 165 may made of a material such as n+ hydrogenated amorphous silicon to which an n-type impurity such as phosphorus is doped at a high concentration, or silicide.

The drain electrode 175 that is disposed at the opposite side of the source electrode 173 with respect to the source electrode 173, and gate electrode 124 on the ohmic contact layers 163 and 165. Herein, the source electrode 173 that is adjacent to the data line 171 that extends in a vertical direction is separated from the data line 171.

One gate electrode 124, one source electrode 173 and one drain electrode 175 form one thin film transistor (TFT) in conjunction with the semiconductor layer 154, and a channel of the thin film transistor is formed at the semiconductor layer 154 between the source electrode 173 and drain electrode 175.

The passivation layer 180 is formed on the interlayer insulating layer 140, source electrode 173, drain electrode 175 and exposed semiconductor layer 154. The passivation layer 180 is made of an inorganic insulator or an organic insulator, and may have a flat surface. As examples of the inorganic insulator, there may be silicon nitride and silicon oxide.

A contact hole 185 that exposes a portion of the drain electrode 175 is formed in the passivation layer 180.

A first seed layer SML1 is disposed on the passivation layer 180 disposed at an intersection part of the gate line 121 and data line 171 illustrated in FIG. 2. In addition, a second seed layer SML2 is disposed on the passivation layer 180 disposed between the data line 171 and source electrode 173 illustrated in FIG. 3.

With reference to FIG. 2, a first bridge B1 that connects the separated data lines 171 is formed while covering the first seed layer SML1. With reference to FIG. 3, a second bridge B2 that connects the data line 171 and source electrode 173 that are separated from each other is formed while covering the second seed layer SML2.

An organic layer 230 and an overcoat 250 that covers the organic layer 230 may be formed on the passivation layer 180. The organic layer 230 may be a color filter. According to another embodiment, the organic layer 230 and overcoat 250 may be formed on the other display panel (not shown) to which a common voltage is applied.

A pixel electrode 191 that is physically and electrically connected to the drain electrode 175 through the contact hole 185 is disposed on the overcoat 250. The pixel electrode 191 may be made of a transparent conductive material such as ITO or IZO, or reflective metal such as aluminum, silver, chromium or an alloy thereof.

The pixel electrode 191 is physically and electrically connected to the drain electrode 175 through the contact hole 185, and applied with a data voltage from the drain electrode 175. The pixel electrode 191 to which the data voltage is applied determines a direction of liquid crystal molecules (not shown) of the liquid crystal layer (not shown) between two electrodes by generating an electric field in conjunction with the common electrodes (not shown) of the other display panel (not shown) to which the common voltage is applied. As described above, according to the determined direction of the liquid crystal molecule, the polarization of light that passes through the liquid crystal layer 3 is changed. The pixel electrode 191 and common electrode forms a capacitor (hereinafter, referred to as “a liquid crystal capacitor”) to maintain the applied voltage after the thin film transistor is turned off.

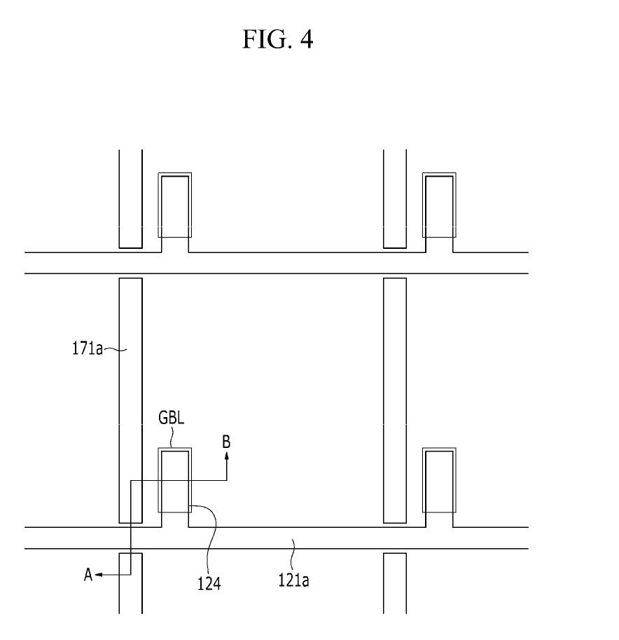

FIGS. 4 to 26 are layout views and cross-sectional views that illustrate a manufacturing method of a thin film transistor array panel according to another exemplary embodiment.

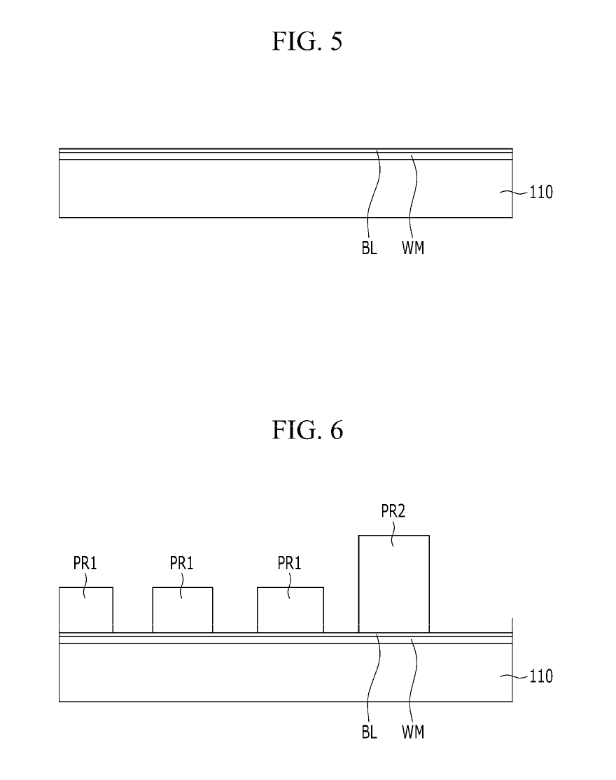

FIG. 4 is a layout view that illustrates an exemplary embodiment, and FIGS. 5 to 10 are cross-sectional views that are taken along the line A-B of FIG. 4.

Referring to FIG. 5, a wiring layer WM and a blocking material layer BL are sequentially deposited on the substrate 110. The wiring layer WM may be formed of a metal material, and the blocking material layer BL may be formed of silicon oxide (SiOx) or silicon nitride (SiNy). However, the blocking material layer BL is not limited to the above material, and the metal that is not deposited when plating is performed by a plating method as described later, for example, titanium (Ti) may be used.

Referring to FIGS. 5 and 6, photosensitive film patterns PR1 and PR2 that have different thicknesses are formed on the blocking material layer BL, the blocking material layer BL and wiring layer WM are sequentially etched by using the photosensitive film patterns PR1 and PR2 as the mask. In this case, a portion of the substrate 110 may be exposed.

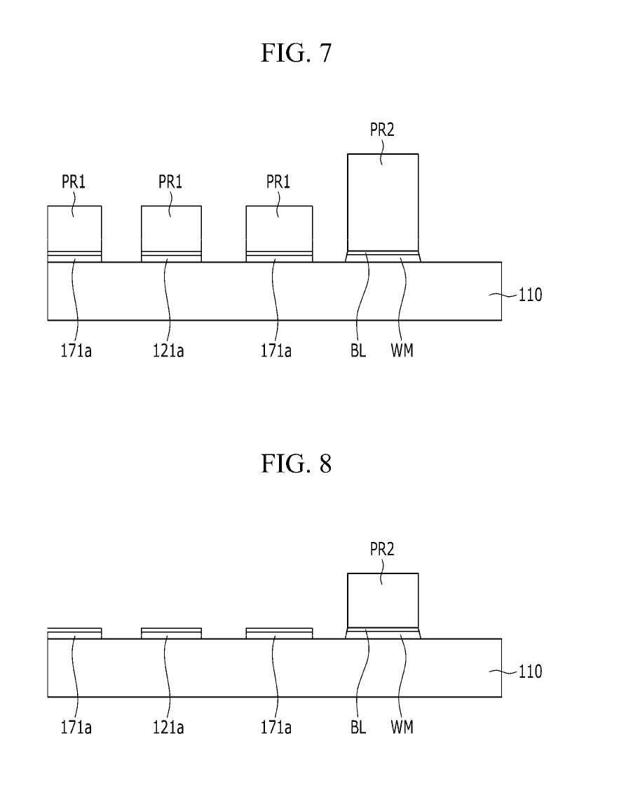

Referring to FIGS. 7 and 8, a portion of the blocking material layer BL is exposed by etchbacking the photosensitive film pattern PR1. In this case, the thickness of the photosensitive film pattern PR2 that has the relatively large thickness is reduced, but it covers the blocking material layer BL.

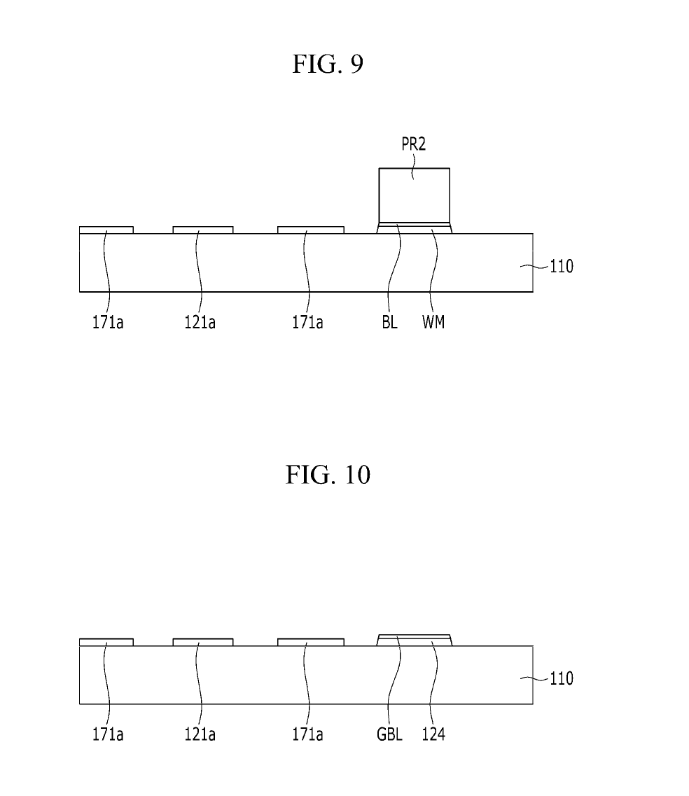

Referring to FIG. 9, the lower gate line 121a and lower data line 171a are formed by etching the exposed portion of the blocking material layer BL by using the remaining photosensitive film pattern PR2 as the mask.

Referring to FIG. 10, the blocking layer GBL is formed on the gate electrode 124 by stripping the remaining photosensitive film pattern PR2.

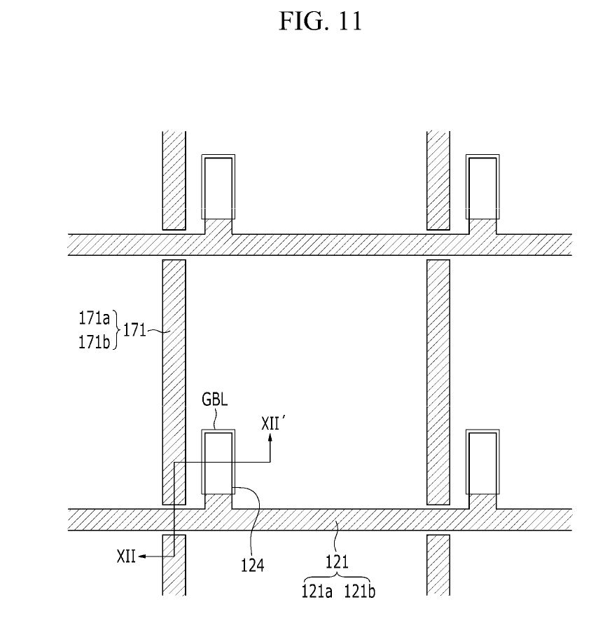

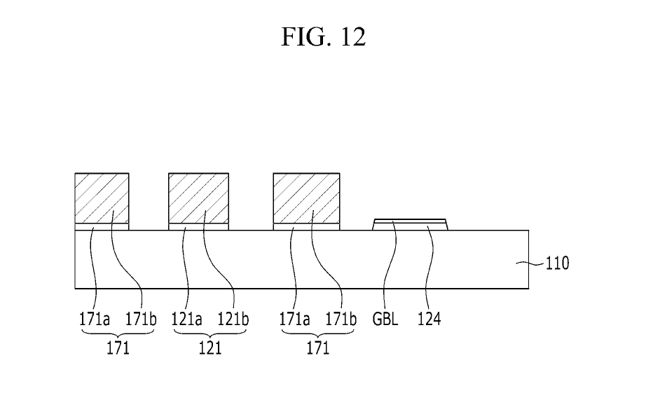

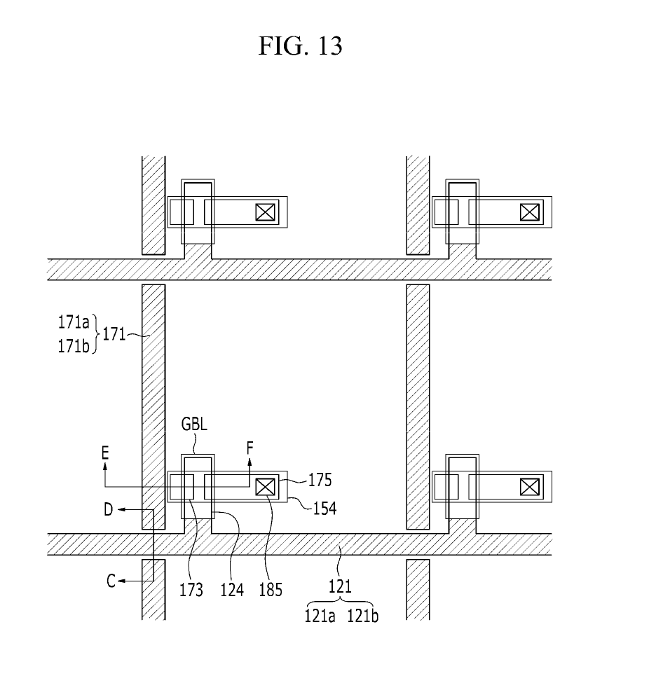

FIG. 11 is a layout view that illustrates steps after the steps illustrated in FIG. 10, and FIG. 12 is a cross-sectional view that is taken along the line XII-XII′ of FIG. 11.

Referring to FIGS. 11 and 12, the upper gate line 121b and upper data line 171b are formed by using the lower gate line 121a and lower data line 171a as a seed layer using an electroless plating method or an electroplating method. In this case, since the gate electrode 124 is covered by the blocking layer GBL, the upper gate line 121b is formed on only the lower gate line 121a. Since the lower gate line 121a is used as the seed layer, the upper gate line 121b may be formed of the substantially same shape as the lower gate line 121a, and since the upper data line 171b uses the lower data line 171a as the seed layer, it may be formed of the substantially same shape as the lower data line 171a.

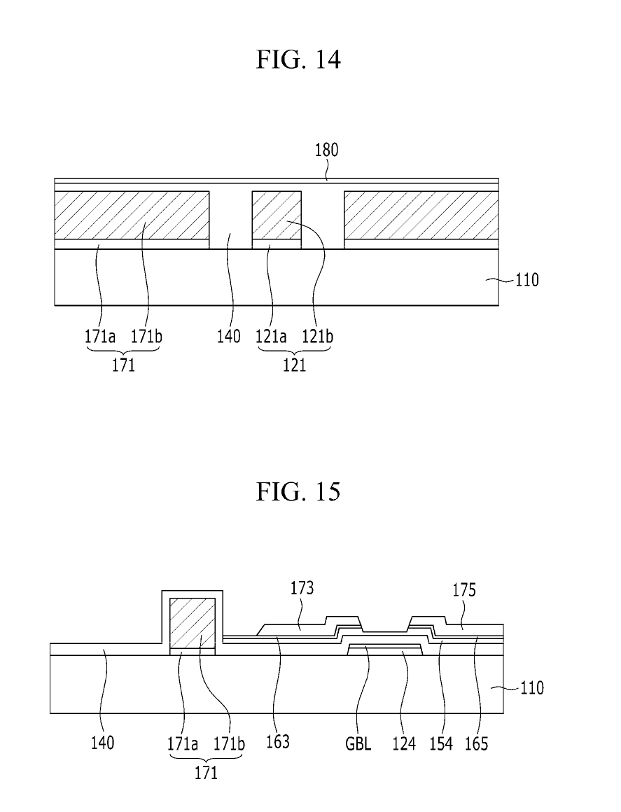

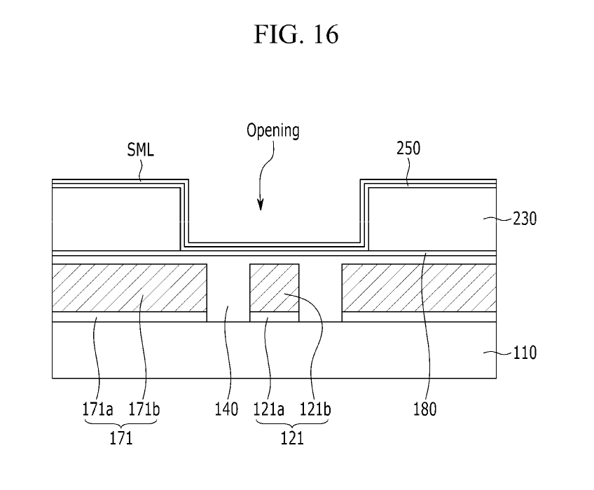

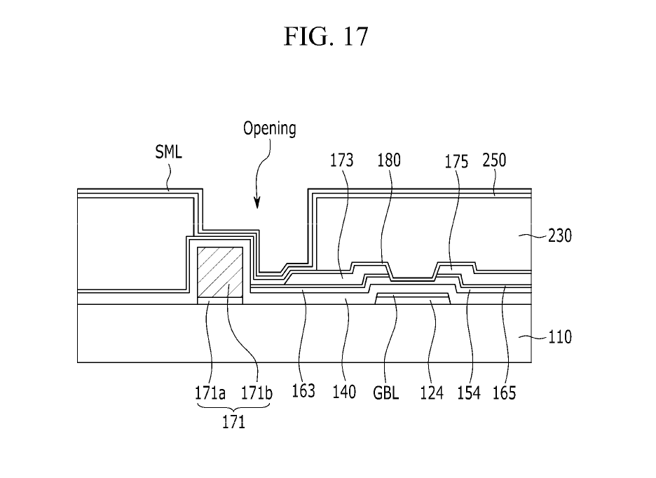

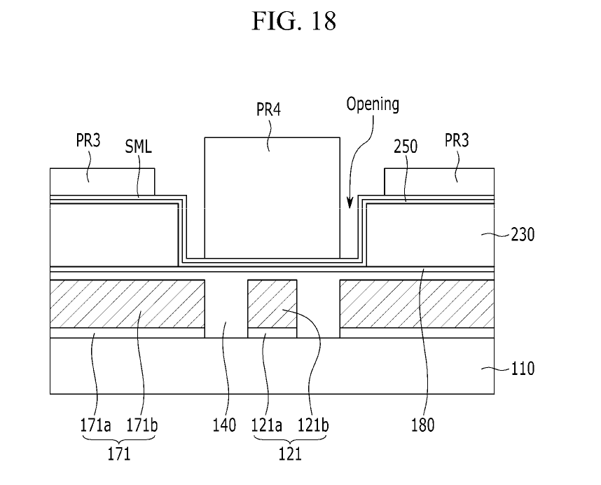

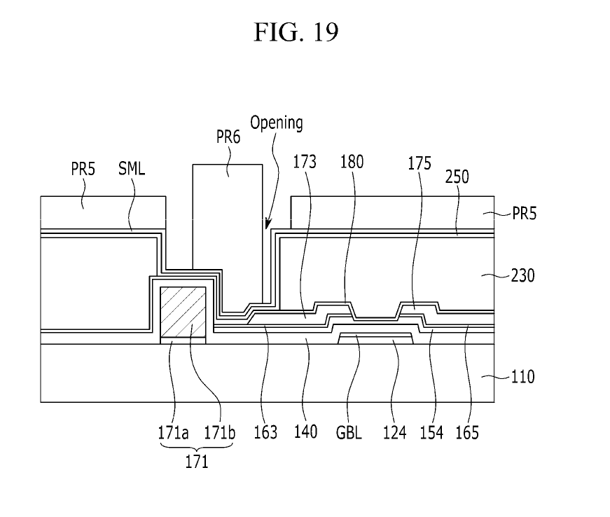

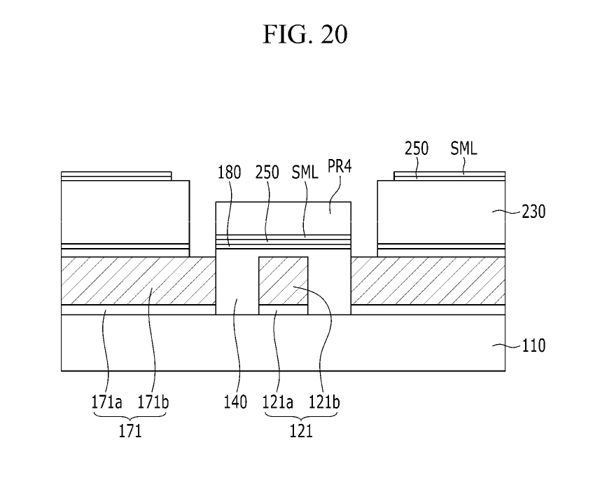

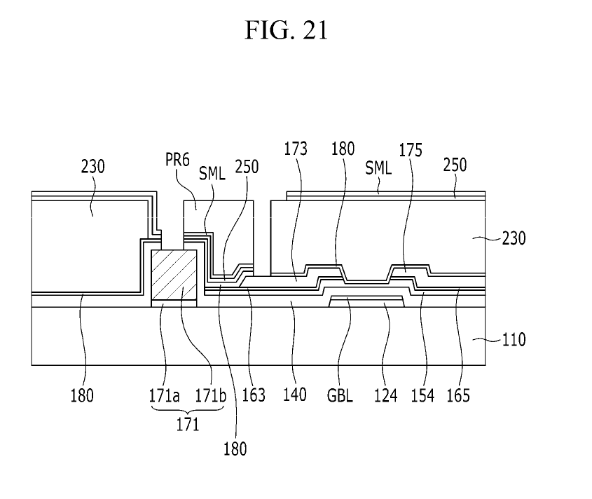

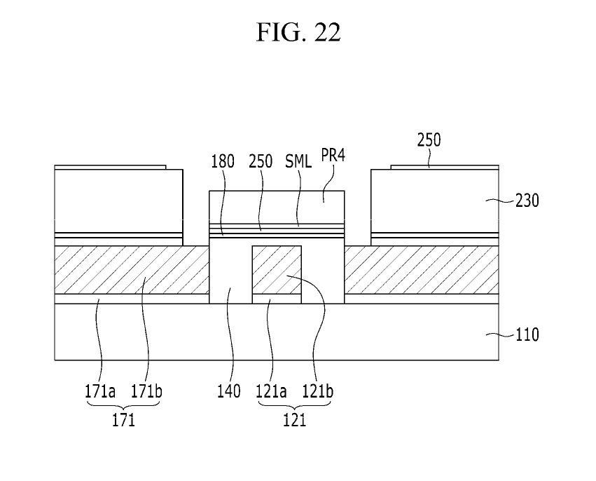

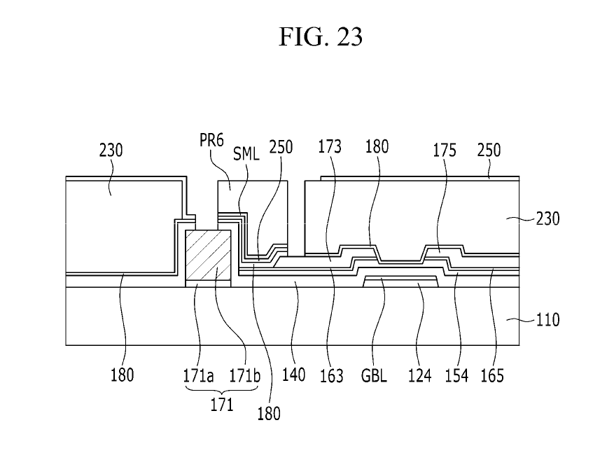

FIG. 13 is a layout view that illustrates a state in which steps are performed after the step illustrated in FIG. 11, FIG. 14, FIG. 16, FIG. 18, FIG. 20 and FIG. 22 are cross-sectional views that are taken along the line C-D of FIG. 13, and FIG. 15, FIG. 17, FIG. 19, FIG. 21 and FIG. 23 are cross-sectional views that are taken along the line E-F of FIG. 13.

Referring to FIG. 14 and FIG. 15, the interlayer insulating layer 140 is formed on the gate line 121, blocking layer GBL and data line 171. The interlayer insulating layer 140 may be formed of silicon nitride (SiNx) or silicon oxide (SiO₂).

In addition, referring to FIG. 15, a semiconductor layer 154 and ohmic contact layers 163 and 165 are formed on the interlayer insulating layer 140. In addition, the drain electrode 175 that is disposed at the opposite side of the source electrode 173 with respect to the source electrode 173, and gate electrode 124 on the ohmic contact layers 163 and 165.

The semiconductor layer 154 and ohmic contact layer 163 and 165 may be formed by a photolithography process using one mask, and the source electrode 173 and drain electrode 175 may be formed by a photolithography process using the other mask. In this case, the ohmic contact layers 163 and 165 may be formed so that they more protrude to the side as compared to the source electrode 173 and drain electrode 175. However, it is not necessary to perform the above process, but the semiconductor layer 154, ohmic contact layers 163 and 165, source electrode 173 and drain electrode 175 may be formed by a photolithography process using one mask.

Herein, the gate electrode 124, the source electrode 173 and the drain electrode 175 form a thin film transistor (TFT) in conjunction with the semiconductor layer 154, and a channel of the thin film transistor is formed at the semiconductor layer 154 between the source electrode 173 and drain electrode 175.

Referring to FIG. 16 and FIG. 17, the passivation layer 180 is formed on the interlayer insulating layer 140, the source electrode 173, the drain electrode 175 and exposed semiconductor layer 154. An organic layer 230 having an opening is formed on the passivation layer 180, and an overcoat 250 may be formed on the passivation layer 180 and the organic layer 230 disposed at the opening. A seed layer SML may be formed on the overcoat 250. The seed layer SML may be a metal layer.

Referring to FIG. 18 and FIG. 19, photosensitive film patterns PR3, PR4, PR5, and PR6 having different thicknesses are formed on the seed layer SML. The third photosensitive film PR3 that is illustrated in FIG. 18 overlaps the data line 171, and the fourth photosensitive film PR4 is disposed at the intersection part of the gate line 121 and data line 171. The fifth photosensitive film PR5 that is illustrated in FIG. 19 is disposed at an overlapping part with the organic layer 230, and the sixth photosensitive film PR6 is disposed in the opening of the organic layer 230.

With reference to FIG. 20 and FIG. 21, the upper surface of the data line 171 that is adjacent to the part through which the gate line 121 passes, and the data line 171 and source electrode 173 which are adjacent to each other are partially exposed by etching the seed layer SML, the cover layer 250, the passivation layer 180 and the interlayer insulating layer 140 by using the photosensitive film patterns PR3, PR4, PR5, and PR6 as the mask. After that, the etchback is performed, the third photosensitive film PR3 and the fifth photosensitive film PR5 that have relatively smaller thicknesses than the fourth photosensitive film PR4 and the sixth photosensitive film PR6 are removed.

The seed layer SML is exposed at the part at which the third photosensitive film PR3 and the fifth photosensitive film PR5 are disposed.

With reference to FIG. 22 and FIG. 23, the exposed seed layer SML is etched at the part at which the third photosensitive film PR3 and the fifth photosensitive film PR5 are disposed. In this case, since the seed layer SML of the part that is covered by the fourth photosensitive film PR4 and the sixth photosensitive film PR6 is protected, it still remains.

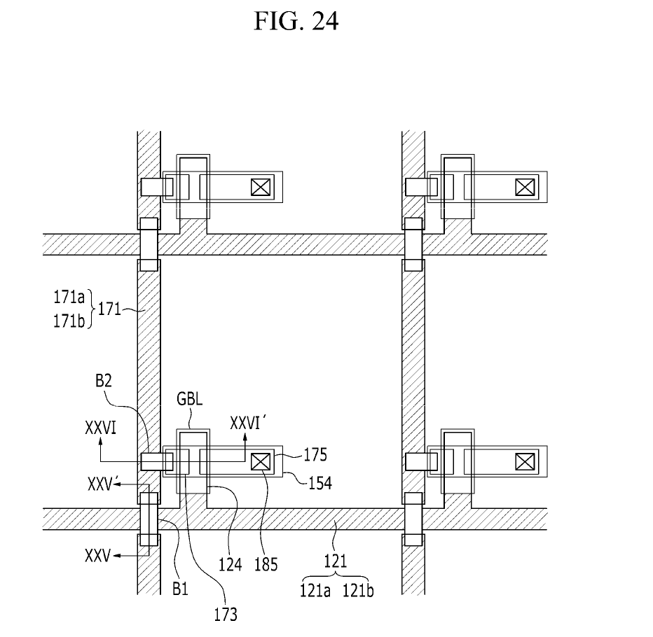

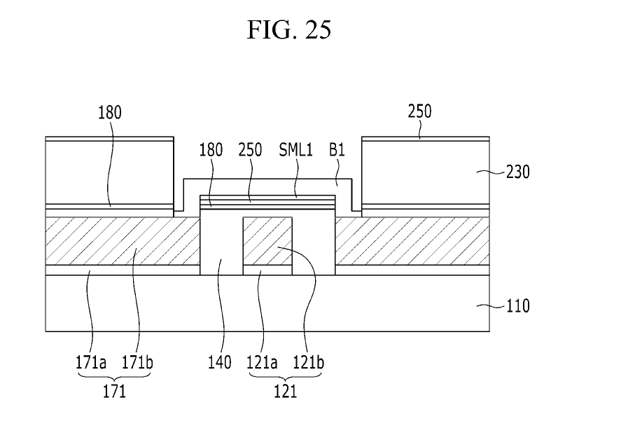

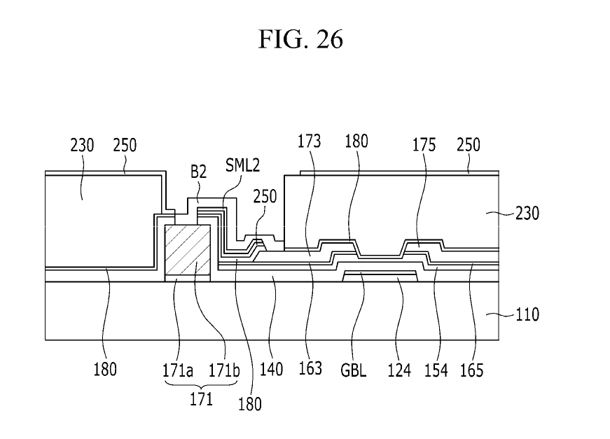

FIG. 24 is a layout view that illustrates steps after the steps illustrated in FIG. 20 and FIG. 21, and FIG. 25 and FIG. 26 are cross-sectional views that are taken along the line XXV-XXV′ of FIG. 24 and the line XXVI-XXVI′ of FIG. 24.

With reference to FIG. 25 and FIG. 26, the first seed layer SML1 and the second seed layer SML2 are formed by stripping the fourth photosensitive film PR4 and the sixth photosensitive film PR6.

With reference to FIG. 24 and FIG. 25, the upper surface of the data line 171 that is adjacent to the part through which the gate line 121 passes is exposed. The first bridge B1 is formed by using the exposed data line 171 and the first seed layer SML1 as a seed using an electroless plating method or an electroplating method. The first bridge B1 connects the separated data line 171 at the intersection part of the gate line 121 and data line 171.

With reference to FIG. 24 and FIG. 26, the second bridge B2 is formed by using the exposed portions of the source electrode 173 and data line 171 andDeletedTextsthe second seed layer SML2 as the seed using the electroless plating method or electroplating method. The second bridge B2 connects the data line 171 and source electrode 173 to each other.

While claimed subject matter has been described in connection with what is presently considered to be practical exemplary embodiments, it is to be understood that the claimed subject matter is not limited to the disclosed embodiments, but, on the contrary, is intended to cover various modifications and equivalent arrangements included within the spirit and scope of the appended claims.

What is claimed is:

1. A thin film transistor array panel, comprising:
a substrate; and
a gate wire including a gate line disposed on the substrate and a gate electrode protruding from the gate line;
the gate wire having a first region where the gate line is disposed, and a second region where the gate electrode is disposed, and a thickness of the gate wire formed in the first region is greater than the thickness of the gate wire that is formed in the second region.

2. The thin film transistor array panel of claim 1, further comprising:
an interlayer insulating layer disposed on the gate line; and
a blocking layer disposed between the gate electrode and the interlayer insulating layer.

3. The thin film transistor array panel of claim 2, wherein:
the blocking layer is formed of an organic layer or an inorganic layer.

4. The thin film transistor array panel of claim 3, wherein:
the inorganic layer includes silicon nitride (SiNx).

5. The thin film transistor array panel of claim 4, wherein:
the gate line comprises a lower gate line disposed at a same layer as the gate electrode and an upper gate line disposed on the lower gate line.

6. The thin film transistor array panel of claim 5, further comprising:
a data line intersecting the gate line;
wherein the data line comprises a lower data line disposed at a the same layer as the gate electrode and an upper data line disposed on the lower data line.

7. The thin film transistor array panel of claim 1, wherein:
the data line is connected by a first bridge at an intersection part of the gate line and the data line.

8. The thin film transistor array panel of claim 7, further comprising:
a source electrode disposed on a semiconductor layer and a drain electrode disposed at an opposite side of the source electrode with respect to the gate electrode;
wherein
the source electrode and the data line are connected by a second bridge.

9. The thin film transistor array panel of claim 8, further comprising:
a passivation layer disposed on the source electrode and the drain electrode;,
wherein a first seed layer is disposed between the passivation layer and the first bridge.

10. The thin film transistor array panel of claim 9, wherein:
a second seed layer is disposed between the passivation layer and the second bridge.

11. The thin film transistor array panel of claim 10, further comprising:
a pixel electrode disposed on the passivation layer; and
an organic layer disposed between the passivation layer and the pixel electrode.

12. The thin film transistor array panel of claim 11, wherein:
the organic layer is a color filter.

13. A method for manufacturing a thin film transistor array panel, comprising:
forming a gate wire comprising a lower gate line extending in a first direction on a substrate and a gate electrode protruding from the lower gate line, and a lower data line extending in a second direction intersecting the first direction;
forming a blocking layer on the gate electrode;
forming an upper gate line and an upper data line on the lower gate line and the lower data line;
forming an interlayer insulating layer covering the gate wire and upper data line;
forming a semiconductor layer on the interlayer insulating layer;
forming a source electrode disposed on the semiconductor layer and a drain electrode disposed at an opposite side of the source electrode with respect to the gate electrode;
forming a passivation layer disposed on the source electrode and drain electrode; and
forming a pixel electrode disposed on the passivation layer.

14. The method of claim 13, wherein:
the lower gate line, the gate electrode and the lower data line are formed by using a sputtering method.

15. The method of claim 14, wherein:
the forming of the upper gate line and the upper data line uses the lower gate line and the lower data line as a seed layer according to an electroless plating method or an electroplating method.

16. The method of claim 15, wherein:
the first blocking layer is formed of an organic layer or an inorganic layer.

17. The method of claim 16, wherein:
the inorganic layer includes silicon nitride (SiNx).

18. The method of claim 13, further comprising:
forming a first bridge that connects the upper data line at an intersection part of the upper gate line and the upper data line.

19. The method of claim 18, wherein:
the forming of the first bridge includes
forming a first seed layer on the passivation layer after the forming of the passivation layer,
forming a first photosensitive film and a second photosensitive film having different thicknesses on the first seed layer,
exposing a portion of the upper data line by etching the first seed layer, the passivation layer, and the interlayer insulating layer by using the first photosensitive film and the second photosensitive film as a mask,
etchbacking the first photosensitive film in order to remove the first photosensitive film,
etching the first seed layer not covered by the second photosensitive film,
exposing the first seed layer by removing the second photosensitive film, and
forming the first bridge by using the exposed first seed layer and exposed upper data line as the seed layer using an electroless plating method or an electroplating method,
wherein the first photosensitive film has a smaller thickness than the second photosensitive film.

20. The method of claim 19, wherein:
the first photosensitive film overlaps the upper data line, and the second photosensitive film is disposed at an intersection part of the upper gate line and the upper data line.

21. The method of claim 20, further comprising:
forming a second bridge that connects the source electrode and the upper data line.

22. The method of claim 21, wherein:
the forming of the second bridge includes
forming a second seed layer on the passivation layer after the forming of the passivation layer,
forming a third photosensitive film and a fourth photosensitive film having different thicknesses on the second seed layer,
exposing a portion of the upper data line by etching the second seed layer, the passivation layer, and the interlayer insulating layer by using the third photosensitive film and the fourth photosensitive film as a mask,
etchbacking the third photosensitive film in order to remove the third photosensitive film,
etching the second seed layer not covered by the fourth photosensitive film,
exposing the second seed layer by removing the fourth photosensitive film, and
forming the second bridge by using the exposed second seed layer and exposed upper data line as the seed layer using an electroless plating method or an electroplating method,
wherein the third photosensitive film has a smaller thickness than the fourth photosensitive film.

23. The method of claim 13, wherein:
the forming of the lower gate line, the lower data line and the blocking layer includes
forming a wiring layer and a blocking material layer on the substrate,
forming photosensitive film patterns having different thicknesses on the wiring layer and the blocking material layer,
sequentially etching the blocking material layer and the wiring layer by using the photosensitive film pattern as a mask,
exposing a portion of an upper side of the blocking material layer by etchbacking the photosensitive film pattern,
etching an exposed portion of the blocking material layer by using the photosensitive film pattern as the mask, and
removing the photosensitive film pattern.
